(19) United States
(12) Patent Application Publication
(10) Pub. No.: US 2016/0126197 A1
(43) Pub. Date: May 5, 2016

(54) SEMICONDUCTOR DEVICE HAVING A STRESS-COMPENSATED CHIP ELECTRODE

(71) Applicant: Infineon Technologies AG, Neubiberg (DE)

(72) Inventors: Kurt Matoy, Villach (AT); Dirk Ahlers, Muenchen (DE); Ulrike Fastner, Villach (AT); Petra Fischer, Wernberg (AT); Karl-Heinz Gasser, Spittal/Drau (AT); Stephan Henneck, Regensburg (DE); Stefan Krivec, Arnoldstein (AT); Florian Weilnboeck, Grafing (DE)

(73) Assignee: Infineon Technologies AG, Neubiberg (DE)

(21) Appl. No.: 14/932,548

(22) Filed: Nov. 4, 2015

(30) Foreign Application Priority Data
Nov. 4, 2014 (DE) 10 2014 116 082.7

(51) Int. Cl. H01L 23/00; H01L 23/495; H01L 29/45; H01L 23/31

(52) U.S. Cl. CPC H01L 23/562; H01L 23/3157; H01L 23/495; H01L 29/45; H01L 24/32; H01L 24/83; H01L 2924/014; H01L 2924/37001; H01L 2224/8321; H01L 2224/83815; H01L 2924/3511

(57) ABSTRACT

A semiconductor device includes a semiconductor chip having a first main surface and a second main surface. A chip electrode is disposed on the first main surface. The chip electrode includes a first metal layer and wherein the first metal layer is arranged between the semiconductor chip and the second metal layer.

### CROSS REFERENCE TO RELATED APPLICATION

This Utility Patent Application claims priority to German Patent Application No. 10 2014 116 082.7, filed Nov. 4, 2014; and which is incorporated herein by reference.

### TECHNICAL FIELD

This invention relates to semiconductor chips having chip electrodes, and in particular to the technique of electrically connecting a chip electrode to an electrically conducting element.

### BACKGROUND

Semiconductor device manufacturers are constantly striving to increase the performance of their products, while decreasing their cost of manufacture. One aspect of the manufacture of semiconductor devices is packaging the semiconductor chips. Packaging often involves bonding a semiconductor chip electrode to an electrical contact element. The achievable bond quality in terms of mechanical robustness and electrical reliability is an important parameter for obtaining high product yields at low expenses.

For these and other reasons there is a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 schematically illustrates a cross-sectional view of an example semiconductor device including a semiconductor chip and a chip electrode disposed on a first main surface of the semiconductor chip and having a stress compensation layer and a pad metal layer.

FIG. 2 schematically illustrates a cross-sectional view of an example semiconductor device including a semiconductor chip and chip electrodes disposed on both main surfaces of the semiconductor chip and each having a stress compensation layer and a pad metal layer.

FIG. 3 schematically illustrates a cross-sectional view of an example semiconductor device including a semiconductor chip, a chip electrode disposed on a first main surface of the semiconductor chip and having a stress compensation layer and a pad metal layer, a layer of solder material and an electrical contact element.

FIG. 4 schematically illustrates a cross-sectional view of the example semiconductor device of FIG. 3 after formation of a solder bond joint.

FIG. 5 schematically illustrates a cross-sectional view of an example semiconductor device similar to the semiconductor device illustrated in FIG. 4, except that the pad metal layer completely transforms into the intermetallic phase during formation of the solder bond joint.

FIG. 6 is a flowchart of an example process of fabricating a chip electrode on a semiconductor chip.

FIG. 7A schematically illustrates a cross-sectional view of a semiconductor chip placed on a carrier and a contact clip placed on the semiconductor chip.

FIG. 7B schematically illustrates a top view of the arrangement illustrated in FIG. 7A.

FIG. 7C schematically illustrates a cross-sectional view of the arrangement of FIG. 7A after being introduced in an oven and formation of solder joints.

FIG. 8 illustrates a schematic view of an embodiment of a method for manufacturing a semiconductor device using a tunnel oven.

FIG. 9 illustrates a schematic view of an embodiment of a method for manufacturing a semiconductor device using a batch process in an oven.

### DETAILED DESCRIPTION

In the following detailed description, reference is made to the accompanying drawings, which form a part thereof, and in which is shown by way of illustration specific embodiments in which the invention may be practiced. In this regard, directional terminology, such as “top”, “bottom”, “front”, “back”, “upper”, “lower”, etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

As employed in this specification, the terms “bonded”, “attached”, “connected”, “coupled” and/or “electrically connected/electrically coupled” are not meant to mean that the elements or layers must directly be contacted together; intervening elements or layers may be provided between the “bonded”, “attached”, “connected”, “coupled” and/or “electrically connected/electrically coupled” elements, respectively. However, in accordance with the disclosure, the above-mentioned terms may, optionally, also have the specific meaning that the elements or layers are directly contacted together, i.e. that no intervening elements or layers are provided between the “bonded”, “attached”, “connected”, “coupled” and/or “electrically connected/electrically coupled” elements, respectively.

Further, the word “over” used with regard to a part, element or material layer formed or located “over” a surface may be used herein to mean that the part, element or material layer be located (e.g. placed, formed, deposited, etc.) “indirectly on” the implied surface with one or more additional parts, elements or layers being arranged between the implied surface and the part, element or material layer. However, the word “over” used with regard to a part, element or material layer formed or located “over” a surface may, optionally, also have the specific meaning that the part, element or material layer be located (e.g. placed, formed, deposited, etc.) “directly on”, e.g. in direct contact with, the implied surface.

Devices containing a semiconductor chip are described herein. In particular, one or more semiconductor chips having a vertical structure may be involved, that is to say that the semiconductor chip may be fabricated in such a way that electric current can flow in a direction perpendicular to the main surfaces of the semiconductor chip. A semiconductor chip having a vertical structure has electrodes on its two main surfaces, that is to say on its top side and bottom side. In particular, a semiconductor power chip having a vertical structure may be involved.

In various other embodiments, a semiconductor chip having a horizontal structure may be involved. A semiconductor chip having a horizontal structure may have electrodes only on one surface, e.g., on its top side surface. In particular, a semiconductor power chip having a horizontal structure may be involved.

The semiconductor chip may be manufactured from specific semiconductor material such as, for example, Si, SiC, SiGe, GaAs, GaN, AlGaN, InGaAs, InAlAs, etc, and, furthermore, may contain inorganic and/or organic materials that are not semiconductors. The semiconductor chips may be of different types and may be manufactured by different technologies.

The semiconductor chip described herein may include one or more logic integrated circuits. In particular, if the semiconductor chip is a power chip, the power semiconductor chip may include one or more logic integrated circuits such as, e.g., a driver circuit to drive the semiconductor power chip and/or one or more sensors such as, e.g., a temperature sensor. The logic integrated circuit may, e.g., be a microcontroller including, e.g., memory circuits, level shifters, etc.

For example, the semiconductor chip described herein may be configured as a power MISFET (Metal Insulator Semiconductor Field Effect Transistor), a power MOSFET (Metal Oxide Semiconductor Field Effect Transistor), an IGBT (Insulated Gate Bipolar Transistor), a JFET (Junction Gate Field Effect Transistor), a HEMT (High Electron Mobility Transistor), a power bipolar transistor or a power diode such as, e.g. a PIN diode or a Schottky diode. By way of example, in vertical power devices, the source contact electrode and the gate contact electrode of a power MISFET or a power MOSFET or a HEMT may be situated on one main surface, while the drain contact electrode of the power MISFET or power MOSFET or HEMT may be arranged on the other main surface. Further, semiconductor power chips such as, e.g. HEMTs, are considered herein which are horizontal devices, with electrodes arranged only on the top surface thereof

The semiconductor chip has chip electrodes (chip pads) disposed on a semiconductor chip main surface. The chip electrodes allow electrical contact to be made with the integrated circuit(s) included in the semiconductor chip. At least one of the chip electrodes includes at least two metal layers, i.e. a stress compensation layer and a pad metal layer. These metal layers may be manufactured with any desired geometric shape. These metal layers may, for example, have the form of a land covering a defined area of the semiconductor main surface over which they are disposed.

Solder material may be applied to the chip electrode to electrically and mechanically connect the semiconductor chip to a chip-external electrical contact element such as, e.g., a carrier or a contact clip. The solder material may be a soft solder material. The solder material may be based on Sn, e.g., may comprise or consist of Sn or an alloy of Sn, in particular Sn(Ag), Sn(Au), Sn(Zn), Sn(Sb), Sn(AgCu) or Sn(CuNiGe).

In the notation used herein for alloys, the primary element (e.g. Sn) is the base or matrix of the alloy, whereas the secondary constituents) enclosed in brackets is (are) the solute(s). By way of example, Sn(Ag) is an example of a binary Sn alloy, Sn(AgCu) is an example of a ternary Sn alloy and Sn(CuNiGe) is an example of a quaternary Sn alloy. The primary element always amounts for equal to or greater than 50 at % of the alloy.

In particular, if the solder material includes Sn, the solder material may include a content of Sn greater than 50 at %, 80 at %, 90 at % or even 95 at %. The solder material may also include a content of 100 at % of Sn. The solder material may, e.g., be free of Pb.

The solder material may be a solder paste including solder metal particles of the above composition. Further, it may contain a flux material in which the solder metal particles are suspended. The solder material may further include spacer particles such as, e.g., Cu particles or Ni-coated Cu particles having a diameter in the range between, e.g., 5 μm and 30 μm.

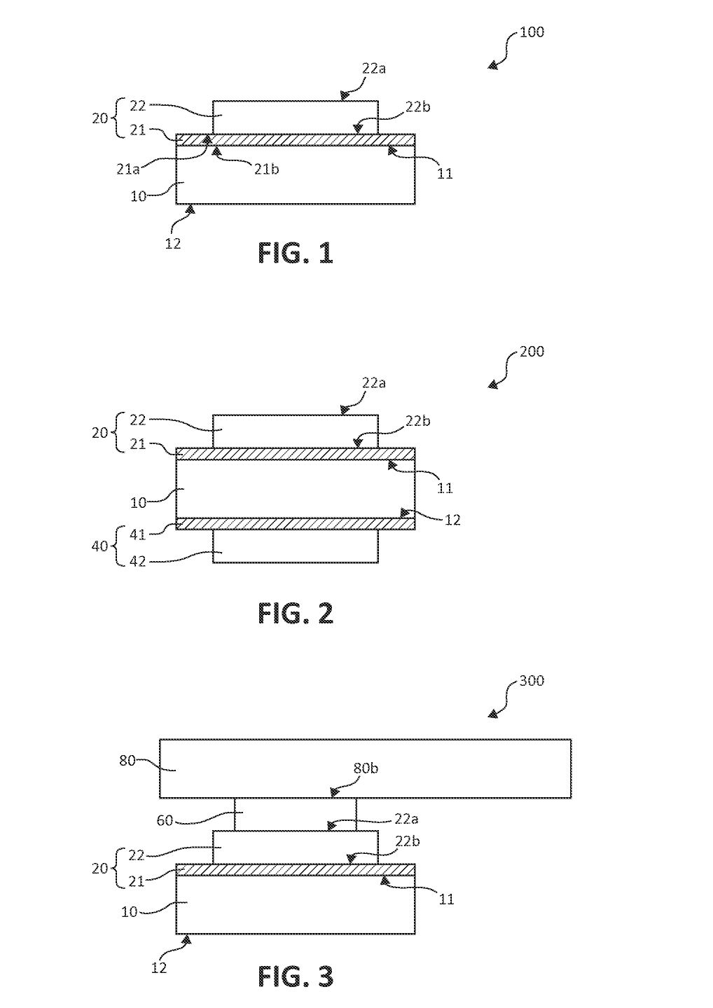

FIG. 1 schematically illustrates an example semiconductor device 100. The semiconductor device 100 includes a semiconductor chip 10 having a first main surface 11 and a second main surface 12 arranged opposite to the first main surface 11. Further, the semiconductor device 100 includes a chip electrode 20, e.g. a load electrode or a control electrode of the semiconductor chip 10. The chip electrode 20 is disposed over the first main surface 11 of the semiconductor chip 10. The chip electrode 20 includes a first metal layer 21 and a second metal layer 22. The second metal layer 22 is arranged over the first metal layer 21.

The first metal layer 21, which is also referred to herein as a stress compensation layer, comprises or consists of a first metal material selected from the group consisting of W, Cr, Ta, Ti and metal alloys of W, Cr, Ta, Ti. By way of example, the first metal layer 21 may comprise or consist of a W alloy, in particular a W(Ti) alloy. The base or matrix metal W, Cr, Ta or Ti amounts to equal to or more than 50 at % of the overall composition. It may also amount to 100 at % of the overall composition.

In particular, the first metal layer 21 may have a composition in which the base or matrix metal W, Cr, Ta or Ti has a content of equal to or more than 70 at %, 80 at % or 90 at %, wherein the secondary constituent(s) (e.g. Ti alone or together with other metal elements) add(s) up to 100 at % of the composition. It is to be noted that residual unwanted impurities may be contained in the composition of the first metal layer 21 which, however, are not specified in the notation of the composition as it is common practice in the art.

The second or pad metal layer 22 of the chip electrode 20 is based on Cu, e.g., may consist of Cu or an alloy of Cu (also denoted as Cu/Cu alloy in the following). The second metal layer 22 has an upper surface 22a which may be configured to be soldered to an electrical contact element (not shown in FIG. 1) as will be described herein in more detail further below. Further, the second metal layer 22 has a lower surface 22b which may, e.g., be in direct contact with an upper surface 21a of the first metal layer 21. A lower surface 21b of the first metal layer may, e.g., be in direct contact with the first main surface 11 of the semiconductor chip 10. It is, however, to be noted that one or more intermediate layers such as, e.g., adhesion layers or barrier layers may be disposed below, between or over the stack of the first metal layer 21 and the second metal layer 22 forming the chip electrode 20.

The first metal layer 21 may have a thickness equal to or greater than 50 nm, 100 nm, 200 nm, 300 nm or 400 nm. Further, the first metal layer 21 may have a thickness equal to or less than 500 nm, 400 nm, 300 nm, 200 nm, 100 nm or 80 nm.

The second metal layer 22 may have a thickness equal to or greater than 6 μm, in particular 7 μm. In particular, the thickness of the second metal layer 22 may be equal to or greater than 9 μm, 11 μm, 13 μm or 15 μm. The thickness of the second metal layer 22 may be equal to or less than 50 μm, 40 μm, 30 μm, 20 μm, 15 μm or 10 μm.

The thickness of the first metal layer 21 is measured between the lower surface 21b and the upper surface 21a thereof, and the thickness of the second metal layer 22 is measured between the lower surface 22a and the upper surface 22b thereof. It is to be noted that both layers 21, 22 may each have a substantial constant thickness (e.g. meaning that thickness tolerance variations are less than ±20%) across their lateral extension.

Further, the first metal layer 21 may cover equal to or more than 60%, 70%, 80% or 90% of the area of the first main surface 11 of the semiconductor chip 10. It is also possible that the entire first main surface 11 of the semiconductor chip 10 is covered by the first metal layer 21.

The second metal layer 22 may also cover an area equal to or more than 60%, 70%, 80% or 90% of the first main surface 11 of the semiconductor chip 10, and, in particular, e.g., the entire first main surface 11. Typically, as illustrated in FIG. 1, the first metal layer 21 extends under the entire lower surface 22b of the second metal layer 22.

The first metal layer 21 may act as a stress compensation layer configured to counteract the internal compressive stress established in the second metal layer 22 when applied as a solderable chip electrode pad metal layer over the semiconductor chip 10.

More specifically, as will be explained in more detail further below, a chip electrode 20 on the basis of a Cu/Cu alloy second metal layer 22 has to have a certain minimum thickness for being solderable. The minimum thickness is needed because the Cu of the second metal layer 22 is consumed during the soldering process and, e.g., during all subsequent temperature budgets by diffusion transport into the solder joint. This removal of Cu from the second metal layer 22 into the solder joint (not shown in FIG. 1) necessitates the second metal layer 22 to have a specific critical minimum thickness so as to avoid a complete consumption of the Cu, which would result in a detachment of the second metal layer 22 from the semiconductor chip 10. On the other hand, a thickness of the second metal layer 22 equal to or greater than the critical minimum thickness guarantees that not the entire Cu of the second metal layer 22 is consumed during soldering, with the effect that at least a thin residual homogeneous Cu/Cu alloy layer is maintained over the first metal layer 21. This thin residual Cu/Cu alloy layer then guarantees the robustness and/or stability and electric reliability of the solder joint.

The thicker the second metal layer 22 the greater is the mechanical mismatching at the interface between the second metal layer 22 and the semiconductor chip 10. More specifically, the second metal layer 22 tends to expand during heating and shrink during cooling much more than the semiconductor material of the semiconductor chip 10 after its application to the semiconductor chip 10 or to the wafer of which the semiconductor chip 10 forms an integral part before singulation. This difference of the thermo-mechanical behavior or CTE (coefficient of thermal expansion) of the second metal layer 22 and the semiconductor chip material causes warpage of the semiconductor chip 10 and/or the semiconductor wafer. Further, the larger the area of the chip electrode 20 on the semiconductor chip 10, the higher is the warpage obtained. If a critical warpage is exceeded, the packaging process and/or the die attach at the customer will become unreliable or even impossible. These difficulties arising from chip warpage may even also be critical for bare die applications.

Further, it is to be noted that mechanical mismatch between the second metal layer 22 of the chip electrode 20 and the semiconductor material of the semiconductor chip 10 specifically compromise semiconductor power devices. This is due to the fact that semiconductor power devices often use very thin semiconductor chips 10 (in order to reduce the internal electrical resistance of the device) and, on the other hand, use large size chip electrodes in order to cope with the relatively high currents involved. These two conditions (thin chip, wide area chip electrode) promote warpage. By way of example, the semiconductor chip 10 disclosed herein may have a thickness of, e.g., equal to or less than 400 μm, 300 μm, 200 μm, 100 μm or 50 μm.

The first metal layer 21 is adapted to reduce the impact of the mechanical mismatch between the second metal layer 22 and the semiconductor chip 10, i.e. to reduce the chip and/or wafer warpage (overall bow thereof). Further, the second metal layer 22 may be dimensioned in thickness to cause as less as possible warpage but, on the other hand, to assure the generation of a proper solder joint between the chip electrode 20 and an electrical contact element (not illustrated in FIG. 1).

It is assumed that the stress compensation or stress relaxation induced by the first metal layer 21 may be attributed to the internal stress of the first metal layer 21 which counteracts the internal stress of the second metal layer 22. As a result, the internal stress of the second metal layer 22 is weakened. This reduction of the overall stress acting on semiconductor chip 10 or wafer reduces or even prevents the occurrence of warpage or bow of the semiconductor chip 10.

The first metal layer (stress compensation layer) 21 may be provided only on the first main surface 11 of the semiconductor chip 10 (see FIG. 1) or only on the second main surface 12 of the semiconductor chip 10 or, as e.g. illustrated in FIG. 2, on both the first and the second main surfaces 11, 12 of the semiconductor chip 10. More specifically, FIG. 2 illustrates an example semiconductor device 200 comprising the semiconductor chip 10 and the chip electrode 20 and having another chip electrode 40 disposed on the second main surface 12 of the semiconductor chip 10, wherein the other chip electrode 40 includes a third metal layer (stress compensation layer) 41 and a second metal layer (pad metal layer) 42. All features including dimensions, materials and other quantities and characteristics recited above for the chip electrode 20, the first metal layer 21 and the second metal layer 22 may apply to the other chip electrode 40, the third metal layer 41 and the fourth metal layer 42, respectively, and reference is made to the description above in order to avoid reiteration. It is to be noted that these features (e.g. dimensions, material, etc.) may be different for the chip electrode 20 and the other chip electrode 40, and all possible combinations of respective features for the chip electrode 20 and the other chip electrode 40 are intended to be disclosed herein. As a specific example, the third metal layer 41 may, e.g., be a pure Ti layer, while the first metal layer 21 may, e.g., be a W(Ti) alloy layer. Further, by way of example, it is also possible that the other chip electrode 40 does not include a third metal layer (stress compensation layer) 41.

It is to be noted that the semiconductor device 200 illustrated in FIG. 2 may, e.g., be a vertical semiconductor chip having a current flow perpendicular to the first and second main surfaces 11, 12 of the semiconductor chip 10. However, it is also possible that the semiconductor chip 10 of semiconductor device 200 has one or more chip electrodes 20 only disposed at the first main surface 11 and that the third metal layer 41 and the fourth metal layer 42 disposed on the second main surface 12 merely provide for a backside metallization of the semiconductor chip 10 used for mounting the semiconductor chip 10 on, e.g., a chip carrier (not illustrated n in FIG. 2) such as, e.g., a leadframe or a DCB (direct copper bonded) ceramic substrate. In this case, the third metal layer 41 and the fourth metal layer 42 may merely provide for heat dissipation and attachment of the semiconductor chip 10 to the carrier but may not have any electrical function.

FIG. 3 illustrates an example semiconductor device 300. The semiconductor device 300 may include the semiconductor device 100, and in this respect reference is made to the above description in order to avoid reiteration. Further, the semiconductor device 300 includes a solder bond layer 60 and an electrical contact element 80. Before soldering, the solder bond layer 60 may be a layer of a solder paste deposited over the upper surface 22a of the second metal layer 22. On the other hand, the electrical contact element 80 may have a lower surface 80b arranged over and, e.g., in direct contact to the solder bond layer 60.

The electrical contact element 80 may, e.g., be a contact clip or a ribbon. The electrical contact element 80 may comprise or consist of a metal material, e.g. of Cu or an alloy of Cu.

The solder material of the solder bond layer 60 may be deposited by, e.g., printing or dispensing a solder material paste on the upper surface 22a of the second metal layer 22. The solder material paste may contain metal particles distributed in a flux as mentioned above.

The solder bond layer 60 may then be heated to a temperature T sufficient to attach the semiconductor chip 10 firmly to the electrical contact element 80. Heating may, e.g., be performed in an oven.

By way of example, the temperature T applied in the oven to the solder material may, e.g., be between 220° C. and 450° C., more particularly between 230° C. and 330° C.

No external pressure may be applied to the arrangement illustrated in FIG. 3 during its stay in the oven. That is, only gravity may control the force or pressure applied to the solder bond layer 60 when exposed to the high temperature T in the oven.

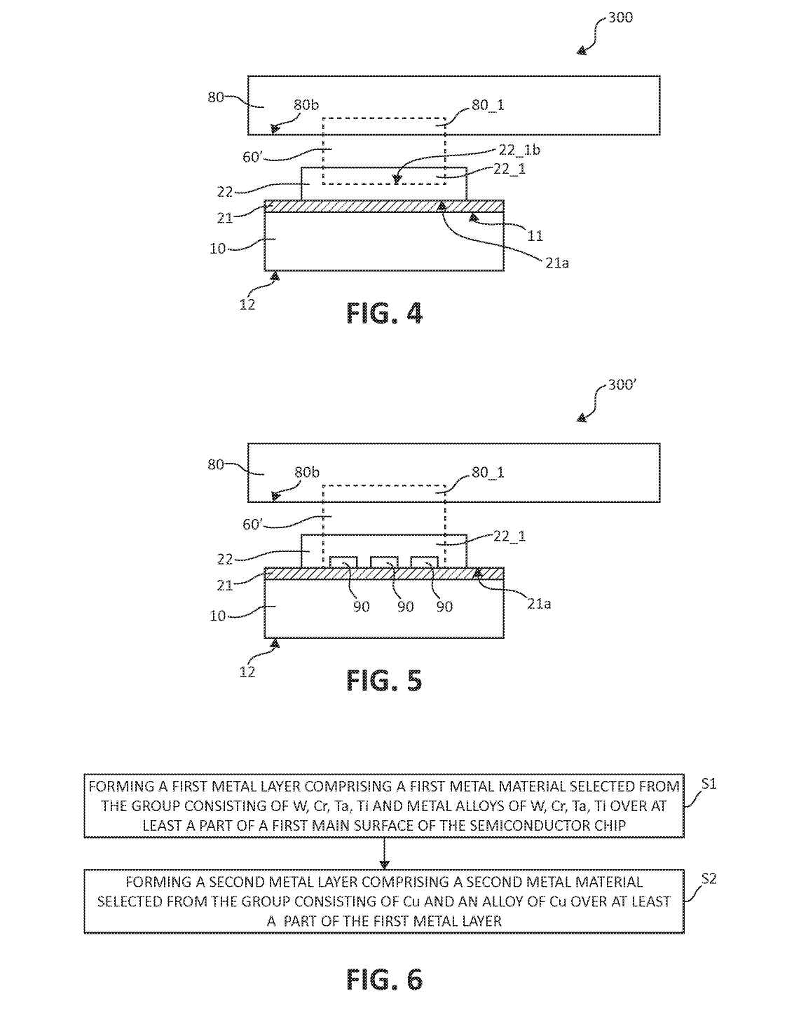

During the stay in the oven the solder bond layer 60 transforms into the solder bond joint 60′ as illustrated in FIGS. 4 and 5. More specifically, the solder material starts melting at a melting temperature. By way of example, Sn has a melting temperature of 232° C. The solder material is exposed to a temperature T which is higher than the melting temperature of the solder material.

FIG. 4 schematically illustrates the semiconductor device 300 after the process of soldering the chip electrode 20 to the electrical contact element 80. As indicated in FIG. 4, the solder bond layer 60 has been transformed into a solder bond joint 60′. Further, as indicated in FIG. 4 by dashed lines, an intermetallic compound (IMC) has been formed in a region 22_1 previously being a part of the second metal layer 22 and/or an intermetallic compound (IMC) has been formed in a region 80_1 previously being a part of the electrical contact element 80. The intermetallic compound regions 22_1 and 80_1 are caused by the diffusion transport of Cu material from the second metal layer 22 and the electrical contact element 80, respectively, into the solder bond joint 60′ during reflow. Note that in contrast to an alloy, which is a solid solution with a continuous range of possible compositions, an intermetallic compound (IMC) has a well defined crystal structure and fixed stoichiometry. Thus, an IMC distinguishes from an alloy of the same composition.

As may be seen from FIG. 4, the IMC region 22_1 does not penetrate the full thickness of the second metal layer 22, that is a residual homogeneous metal layer is preserved between the upper surface 21a of the first metal layer 21 and the bottom 22_1b of the IMC region 22_1. This residual homogeneous metal layer guarantees that the solder bond joint 60′ remains stable and does not delaminate under mechanical load.

FIG. 5 illustrates a semiconductor device 300′ that is identical to the semiconductor device 300 except that the second metal layer 22 has a thickness less than the critical minimum thickness thereof. By way of example, the thickness of the second metal layer 22 in FIG. 5 may be less than 7 μm, in particular 6 μm. In this case the IMC region 22_1 reaches as far as down to the upper surface 21a of the first metal layer 21, that is the Cu of the second metal layer 22 is fully consumed under the solder bond joint 60′. As a consequence, voids 90 may generate in the vicinity of the upper surface 21a of the first metal layer 21 and may cause the solder bond joint 60′ to become fragile. It is to be noted that Sn-based solder materials have a considerable higher Cu consumption than Pb-based solder materials.

FIG. 6 illustrates an example process of manufacturing a chip electrode on a semiconductor chip. At S1 a first metal layer comprising a first metal material selected from the group consisting of W, Cr, Ta, Ti and metal alloys of W, Cr, Ta, Ti is formed over at least a part of a first main surface of the semiconductor chip. The formation of the first metal layer may be performed on wafer level, i.e. before chip singulation. As mentioned before, a third metal layer similar to the first metal layer may be formed on the opposite (second) main surface of the semiconductor chip, if desired, see FIG. 2.

Forming of the first metal layer may be performed by PVD (physical vapor deposition), e.g. sputtering, or by CVD (chemical vapor deposition). Other processes of depositing the first metal layer may also be available.

Then, at S2, a second metal layer including a second metal material selected from the group consisting of Cu and an alloy of Cu is formed over at least a part of the first metal layer. The second metal layer may, e.g., be formed by PVD, e.g. sputtering, galvanic deposition or electroless deposition.

Sputtering allows to produce high-purity metal layers with very few impurities and defects. On the other hand, galvanic deposition, also known as electrochemical deposition (ECD) allows for high deposition rates with, however, increased impurity content in the layer. In particular, ECD layers have a significant sulfur contribution which, among other structural differences, allow to distinguish between sputtered layers and galvanically deposited layers.

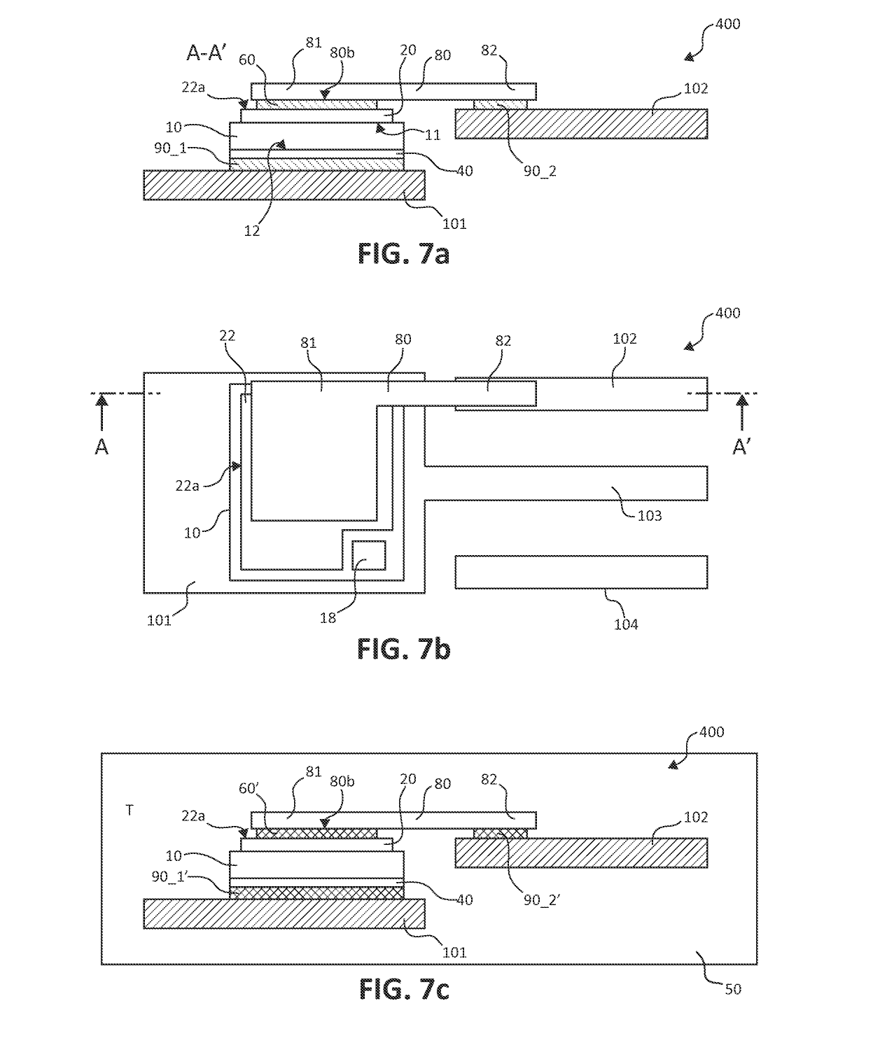

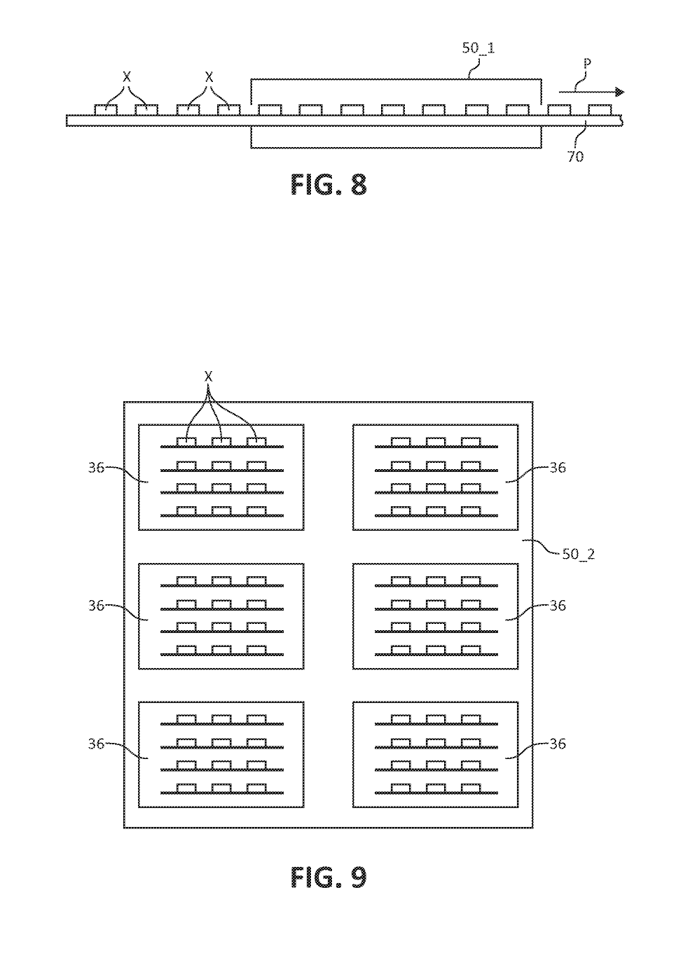

FIGS. 7A-7C illustrate example stages of manufacturing a semiconductor device 400 in accordance with one embodiment. The disclosure below is, in some aspects, more detailed than the disclosure of the aforementioned embodiments. It is to be noted that details described in connection with FIGS. 7A-7C may be apply to or be combined with the concepts and aspects described in the aforementioned embodiments. Vice versa, features and concepts disclosed in relation to the aforementioned embodiments may apply to or be combined with the disclosure of the embodiment explained with reference to FIGS. 7A-7C.

FIG. 7A schematically illustrates a carrier 100, e.g., a leadframe or a DCB. In the following, without loss of generality, the carrier 100 is exemplified by a leadframe 100. The leadframe 100 is illustrated in a plan view (FIG. 7B) and a cross-sectional view along the line A-A′ (FIG. 7A). The leadframe 100 may include a die pad 101, a first lead 102, a second lead 103 and a third lead 104. The leads 102-104 may protrude essentially in parallel from one side of the die pad 101. The second lead 103 may be continuous with one side of the die pad 101. The die pad 101 and the leads 102-104 may be linked by dams (tie bars), which are not illustrated in the figures for the sake of clarity. The leads 102-104 may optionally be arranged in a different plane than the die pad 101, but may alternatively be arranged in the same plane.

The leadframe 100 may, e.g., comprise or consist of Cu or a Cu alloy. The leadframe 100 may have a thickness in the range between 100 μm and 1 mm or may even be thicker. The leadframe 100 may have been manufactured by punching, milling or stamping a metallic plate.

FIGS. 7A-7C schematically illustrate the semiconductor chip 10 being disposed over the die pad 101. In one embodiment further power semiconductor chips may be placed on the same die pad 101 or on further die pads of the leadframe 100 which are not illustrated in FIGS. 7A-7C.

The chip electrode 20 is arranged on the first main surface 11 and the other chip electrode 40 is arranged on the second main surface 12 of the semiconductor chip 10. The chip electrodes 20, 40 are load electrodes. Furthermore, a third chip electrode 18 may be disposed on the first main surface 11 of the semiconductor chip 10. The third chip electrode 18 may be a control electrode. The top surface of the die pad 101 may be larger in size than the second main surface 12 of the semiconductor chip 10. As mentioned before, the third chip electrode 18 (control electrode) may also be connected to a clip (similar to contact element 80, not shown) by using the same concept (e.g. layers 21, 22, 60) as described above.

The semiconductor chip 10 may be configured as a power device, for example, a power transistor such as, e.g., a MOSFET, IGBT, JFET, power bipolar transistor, or a power diode. In the case of a power MOSFET or a JFET, the chip electrode 20 is a source electrode, the other chip electrode 40 is a drain electrode, and the third chip electrode 18 is a gate electrode. In the case of an IGBT, the chip electrode 20 is an emitter electrode, the other chip electrode 40 is a collector electrode, and the third chip electrode 18 is a gate electrode. In the case of a power bipolar transistor, the chip electrode 20 is an emitter electrode, the other chip electrode 40 is a collector electrode, and the third chip electrode 18 is a base electrode. In the case of a power diode, the load chip electrodes 20, 40 are cathode and anode, respectively, and there is no third chip electrode. During operation, voltages higher than 5, 50, 100, 500 or 1000 V may be applied between the load chip electrodes 20, 40.

The arrangement shown in FIG. 7A may be established in a sequential pick-and-place build-up process. First, a solder bond layer 90_1 of solder material may be applied over the die pad 101. The semiconductor chip 10 may then be placed over the solder bond layer 90_1 with its second main surface 12 facing the die pad 101. The solder bond layer 60 may be applied onto the chip electrode 20 prior to or after placing the semiconductor chip 10 over the die pad 101. Simultaneously or at any other time, a solder bond layer 90_2 may be applied to the first lead 102. The solder bond layers 60, 90_1, 90_2 may be deposited by printing, dispensing or any other appropriate technique as mentioned before.

Then, the contact clip 80 is placed over the first lead 102 and the semiconductor chip 10. The contact clip 80 has a first contact area 81 which faces the chip electrode 20 and a second contact area 82 which faces the first lead 102.

The contact clip 80 may be manufactured from a metal or a metal alloy as mentioned above. The shape of the contact clip 80 is not limited to any size or geometric shape. The contact clip 80 may have the shape as exemplified in FIGS. 7A-7B, but other shapes are also possible. In one embodiment, the contact clip 80 may have a thickness in the range from, e.g., 100 μm to 800 μm. The contact clip 80 may be fabricated by stamping, punching, pressing, cutting, sawing, milling or any other appropriate technique. The bottom surface of the contact clip 80 may, e.g., have a surface finish layer of silver or gold. Optionally, a NiP layer may be sandwitched between the metal of contact clip 80 (e.g. Cu or a Cu alloy) and the silver or gold layer. The silver or gold layer may, e.g., have a thickness in the range from 10 to 200 μm.

FIG. 7C schematically illustrates that the arrangement illustrated in FIGS. 7A-7B is introduced into the oven 50. In the oven 50, the solder bond layers 60, 90_1, 90_2 may simultaneously be heated to a temperature T in order to transform the solder bond layers 60, 90_1, 90_2 into respective solder bond joints 60′, 90_1′, 90_2′. The oven process may be performed as described above, in particular in view of application of no external pressure, temperature T and solder materials used.

FIG. 8 schematically illustrates an oven process in accordance with one embodiment. Carriers 100 together with the semiconductor chips 10 and, optionally, electrical contact elements (e.g. contact clips) 80 are referred to as arrangements X. Arrangements X are placed on a conveyor 70. The conveyor 70 may, for example, be driven by a step motor and moves the arrangements X in a direction indicated by arrow P in FIG. 8. After the placement of the arrangements X on the conveyor 70, the arrangements X pass through a tunnel oven 50_1. In the tunnel oven 50_1 the solder bond layers 60, 90_1, 90_2 are exposed to heat to obtain a maximum temperature T. The staying time of the arrangements X in the tunnel oven 50_1 may either be controlled by the velocity of the conveyor 70 if a continuous process is used (i.e. the conveyor 70 is driven with a constant velocity) or by a time interval during which the conveyor is stopped in an intermittent operation, if a semi-continuous process is used. The staying time should be large enough to allow a complete reflow of solder material. Pressure may be reduced in the tunnel oven 50_1 below ambient pressure (i.e. a vacuum may be applied).

FIG. 9 illustrates a schematic view of a further oven process used for soldering the arrangements X. Here, the arrangements X are placed in one or more magazines 36. Subsequently, the magazine 36 and possibly further magazines 36 are placed or introduced in an oven 502. In oven 502, similar to tunnel oven 50_1, the solder bond layers 60, 90_1, 90_2 are exposed to heat to obtain a maximum temperature T. Pressure may be reduced in the oven 50_2 below ambient pressure (i.e. a vacuum may be applied). After elapse of the staying time, the one or more magazines 36 are removed from the oven 50_2.

After solder reflow, the semiconductor chip 10, the electrical element 80 and, e.g., the carrier 100 may at least partly be surrounded or embedded in at least one electrically insulating material (not shown). The electrically insulating material may form an encapsulation body. The encapsulation body may comprise or be made of a mold material or a laminate. Various techniques may be employed to form the encapsulation body of the mold material, for example compression molding, injection molding, powder molding or liquid molding. Further, if the encapsulation body is made of a laminate, the encapsulation body may have the shape of a piece of a layer, e.g. a piece of a sheet or foil that is laminated on top of the semiconductor power chip and the electrically conducting carrier. The encapsulation body may form part of the periphery of the package, i.e. may at least partly define the shape of the semiconductor device.

The electrically insulating material may include or be made of a thermoset material or a thermoplastic material. A thermoset material may, e.g., be made on the basis of an epoxy resin. A thermoplastic material may, e.g., include one or more materials of the group of polyetherimide (PEI), polyether-sulfone (PES) polyphenylene-sulfide (PPS) or polyamide-imide (PAI).

A variety of different types of semiconductor devices may be configured to use the chip electrode 20, 40 as described herein. By way of example, a semiconductor device in accordance with the disclosure may constitute, e.g., a power supply, a DC-DC voltage converter, an AC-DC voltage converter, a power amplifier, and many other power or non-power devices.

Further, the semiconductor devices described herein may be uses in many different applications, including, e.g., automotive applications in which high device robustness is needed.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a semiconductor chip having a first main surface and a second main surface; and
a chip electrode disposed on the first main surface of the semiconductor chip, wherein the chip electrode comprises:
a first metal layer comprising a first metal material selected from the group consisting of W, Cr, Ta, Ti and metal alloys of W, Cr, Ta, Ti; and
a second metal layer comprising a second metal material selected from the group consisting of Cu and an alloy of Cu, wherein the first metal layer is arranged between the semiconductor chip and the second metal layer.

2. The semiconductor device of claim 1, wherein the first metal layer is a W(Ti) alloy layer.

3. The semiconductor device of claim 1, wherein the first metal layer is a metal alloy of a base metal of W, Cr, Ta or Ti having a base metal content equal to or more than 70 at %.

4. The semiconductor device of claim 1, wherein the second metal layer has a thickness equal to or greater than 6 μm.

5. The semiconductor device of claim 1, wherein the first metal layer has a thickness equal to or greater than 50 nm.

6. The semiconductor device of claim 1, wherein the first metal layer has a thickness equal to or less than 500 nm.

7. The semiconductor device of claim 1, wherein the first metal layer is configured to reduce the chip warpage.

8. The semiconductor device of claim 1, wherein the semiconductor chip is a power chip and the chip electrode is a first load electrode of the semiconductor chip.

9. The semiconductor device of claim 8, wherein the first load electrode covers equal to or more than 60% of the area of the first main surface.

10. The semiconductor device of claim 1, further comprising:
another chip electrode disposed on the second main surface of the semiconductor chip, wherein the another chip electrode comprises:
a third metal layer comprising a third metal material selected from the group consisting of W, Cr, Ta, Ti and metal alloys of W, Cr, Ta, Ti; and
a fourth metal layer comprising a fourth metal material selected from the group consisting of Cu and an alloy of Cu, wherein the third metal layer is arranged between the semiconductor chip and the fourth metal layer.

11. The semiconductor device of claim 10, wherein the fourth metal layer has a thickness equal to or greater than 6 μm.

12. The semiconductor device of claim 1, further comprising:
an electrical contact element; and
a solder bond layer attaching the electrical contact element to the chip electrode.

13. The semiconductor device of claim 12, wherein the solder material of the solder bond layer is selected from the group consisting of Sn and alloys of Sn, including Sn(Ag), Sn(Au), Sn(Zn), Sn(Sb), Sn(AgCu) and Sn(CuNiGe).

14. The semiconductor device of claim 12, wherein the electrical contact element is a contact clip.

15. The semiconductor device of claim 14, further comprising:
a leadframe, wherein another chip electrode disposed on the second main surface of the semiconductor chip is mounted to the leadframe.

16. The semiconductor device of claim 15, further comprising:
an electrically insulating material forming an encapsulation body, the electrically insulating material at least partially surrounds the semiconductor chip, the contact clip and the leadframe.

17. A method of bonding an electrical contact element to a chip electrode of a semiconductor chip, wherein the chip electrode comprises a first metal layer comprising a first metal material selected from the group consisting of W, Cr, Ta, Ti and metal alloys of W, Cr, Ta, Ti and a second metal layer overlying the first metal layer and comprising a second metal material selected from the group consisting of Cu and an alloy of Cu, the method comprising:
placing the contact element over the chip electrode, wherein a layer of solder material is provided between the chip electrode and the contact element; and
applying heat to the layer of solder material to form a solder bond between the chip electrode and the contact element.

18. The method of claim 17, wherein applying heat comprises placing the semiconductor chip and the contact element in a reflow soldering oven.

19. The method of claim 18, wherein no external pressure is applied to the contact element and the semiconductor chip while in the reflow soldering oven.

20. A semiconductor device, comprising:
a semiconductor chip having a first main surface and a second main surface; and
a chip electrode disposed on the first main surface of the semiconductor chip, wherein the chip electrode comprises:
a stress compensation layer made of metal or a metal alloy, configured to counteract internal compressive stress; and
a pad layer made of metal, wherein the stress compensation layer is arranged between the semiconductor chip and the pad layer, and the stress compensation layer is made of a metal different than the pad layer.

21. The semiconductor device of claim 20, comprising:
a third layer made of metal disposed on the second main surface; and
a fourth layer made of metal disposed on the third layer, wherein the fourth layer is made of a metal different than the third layer.
